(19) United States
(12) Patent Application Publication
(10) Pub. No.: US 2022/0385041 A1
(43) Pub. Date: Dec. 1, 2022

(54) EMITTER WITH VARIABLE LIGHT REFLECTIVITY

(71) Applicant: Lumentum Operations LLC, San Jose, CA (US)

(72) Inventors: Jun YANG, Cupertino, CA (US); Eric R. HEGBLOM, Sunnyvale, CA (US); Guowei ZHAO, Milpitas, CA (US); Matthew Glenn PETERS, Menlo Park, CA (US)

(21) Appl. No.: 17/305,778

(22) Filed: Jul. 14, 2021

Related U.S. Application Data
(60) Provisional application No. 63/202,104, filed on May 27, 2021.

(51) Int. Cl. H01S 5/183; H01S 5/34

(52) U.S. Cl. CPC H01S 5/18361; H01S 5/3416; H01S 5/18311

(57) ABSTRACT

In some implementations, an emitter may include a substrate and a set of layers on the substrate. The set of layers may include a first mirror, a second mirror that includes a partial reflector and an additional layer, and at least one active region between the first mirror and the second mirror. A first reflectivity of the second mirror at a lateral center of the second mirror may be different than a second reflectivity of the second mirror at a lateral edge of the second mirror.

### CROSS-REFERENCE TO RELATED APPLICATION

This Patent Application claims priority to U.S. Provisional Patent Application No. 63/202,104, filed on May 27, 2021, and entitled “EMITTER WITH A CURVED OR STEPPED SURFACE.” The disclosure of the prior Application is considered part of and is incorporated by reference into this Patent Application.

### TECHNICAL FIELD

The present disclosure relates generally to lasers and to an emitter with variable light reflectivity.

### BACKGROUND

A vertical-emitting device, such as a vertical cavity surface emitting laser (VCSEL), is a laser in which a beam is emitted in a direction perpendicular to a surface of a substrate (e.g., vertically from a surface of a semiconductor wafer). Multiple vertical-emitting devices may be arranged in an array with a common substrate.

### SUMMARY

In some implementations, a VCSEL includes a substrate and a set of layers on the substrate. The set of layers may include a first mirror, a second mirror that includes a partial reflector and an additional layer, and at least one active region between the first mirror and the second mirror, where a first thickness of the second mirror at a lateral center of the second mirror is different than a second thickness of the second mirror at a lateral edge of the second mirror.

In some implementations, an emitter includes a substrate and a set of layers on the substrate. The set of layers may include a first mirror, a second mirror that includes a partial reflector and an additional layer, and at least one active region between the first mirror and the second mirror, where a first reflectivity of the second mirror at a lateral center of the second mirror is different than a second reflectivity of the second mirror at a lateral edge of the second mirror.

In some implementations, a method includes forming a set of layers on a substrate, where the set of layers include a first mirror, a second mirror that includes a partial reflector and an additional layer, and at least one active region between the first mirror and the second mirror. The method may include applying a photoresist layer on the additional layer, patterning the photoresist layer, and etching the additional layer using the photoresist layer to form a curved surface or a stepped surface on the additional layer.

### BRIEF DESCRIPTION OF THE DRAWINGS

FIGS. 1A-1B are diagrams depicting a top view of an example emitter and a cross-sectional view of the example emitter along the line X-X, respectively.

FIGS. 2-8 are cross-sectional views of example embodiments of an emitter.

FIG. 9 is a flowchart of an example process relating to forming an emitter with variable light reflectivity.

### DETAILED DESCRIPTION

The following detailed description of example implementations refers to the accompanying drawings. The same reference numbers in different drawings may identify the same or similar elements.

A vertical cavity surface emitting laser (VCSEL) may have one or more active regions embedded in a cavity of the VCSEL between a top distributed Bragg reflector (DBR) (e.g., a p-DBR) and a bottom DBR (e.g., n-DBR). An active region may include a p-i-n junction. In some examples, a VCSEL may include multiple (e.g., two or three) p-i-n junctions connected vertically in series with tunnel junctions between each p-i-n junction. Such a VCSEL may be referred to as a multi junction VCSEL. A tunnel junction is a p-n junction formed by a very heavily doped p-type (referred to as p++) semiconductor and a very heavily doped n-type (referred to as n++) semiconductor, which may have a doping level from 10¹⁹ to 10²⁰ cm⁻³. Due to a quantum tunneling effect, electrons are converted to holes through the tunnel junction. Relative to a VCSEL that employs a single active region, a VCSEL that employs multiple active regions and one or more tunnel junctions provides higher slope efficiency (e.g., in watts per amp) and higher power conversion efficiency. Thus, a VCSEL with multiple active regions (or an array thereof) is useful for applications in light detection and ranging (LIDAR) and three-dimensional (3D) sensing, including direct time-of-flight (dToF) applications and indirect time-of-flight (iToF) applications.

Relative to a VCSEL that employs a single active region, a VCSEL that employs multiple active regions and one or more tunnel junctions may include a longer cavity and fewer layers of the top DBR to accommodate more gain material and maximize slope efficiency. However, this may degrade carrier and lateral mode confinement. To increase current and mode confinement, additional oxidation layers may be utilized in a VCSEL. However, the additional oxidation layers increase resistance, worsen thermal conductivity, and increase beam divergence. Under high-current operating conditions, the additional oxidation layers may not sufficiently control lateral modes. Moreover, in LIDAR applications that require a long sensing range and a far-field beam profile that meets strict standards, oxide confinement for lateral mode control may be insufficient.

As described herein, an emitter, such as a VCSEL, may include a set of layers (e.g., epitaxial layers) that include a first mirror (e.g., a bottom mirror), a second mirror (e.g., a top mirror), and at least one active region between the first mirror and the second mirror. The second mirror may include a partial reflector and an additional layer on the partial reflector. The partial reflector may be a reflector with partial transmission and/or partial reflection, and may include a DBR (e.g., a p-DBR), multiple layers of the DBR, a single layer of the DBR, and/or one or more semiconductor layers. The additional layer may include a dielectric layer, a semiconductor contact layer, and/or a semiconductor cap layer. Thus, the partial reflector and the additional layer may together define a reflector (e.g., the top mirror) of the emitter. In some implementations, the second mirror may be configured to provide a reflectivity at a lateral center of the second mirror that is different than a reflectivity at a lateral edge of the second mirror. For example, the lateral center of the second mirror may have a different thickness than a lateral edge of the second mirror. As an example, the additional layer may have a curved surface and/or a stepped surface. In this way, reflectivity of the second mirror varies according to lateral position, thereby enhancing lateral mode control and selection. Accordingly, the emitter may provide increased output power and increased total device efficiency without increasing current. In addition, the emitter may reduce output power spectral width to thereby increase the usable power through wavelength-sensitive optics and filters. Furthermore, the emitter may reduce far-field beam divergence to thereby increase the usable power through external optics.

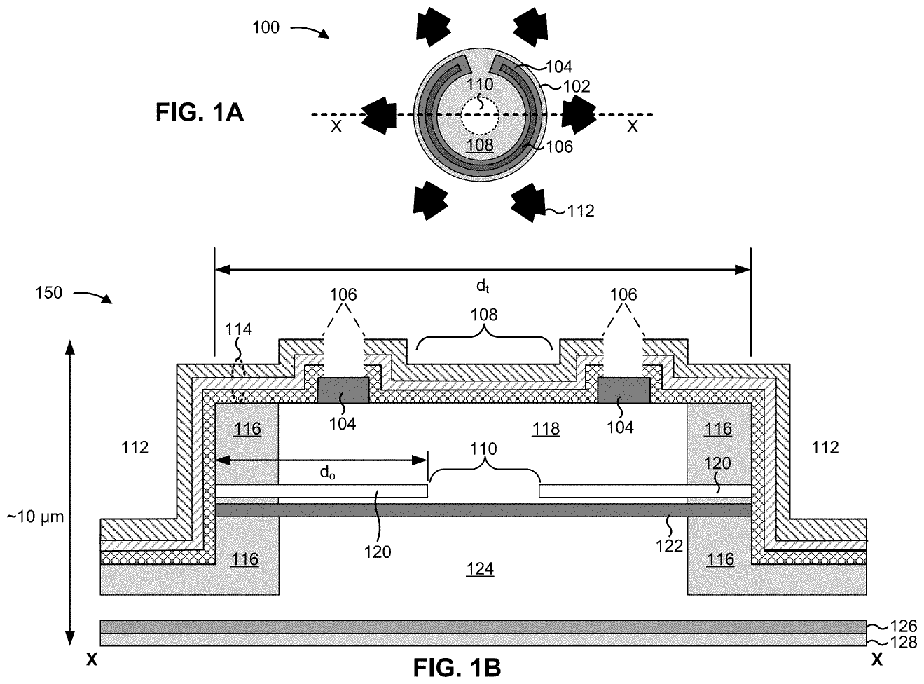

FIGS. 1A and 1B are diagrams depicting a top view of an example emitter 100 and a cross-sectional view 150 of example emitter 100 along the line X-X, respectively. As shown in FIG. 1A, emitter 100 may include a set of emitter layers constructed in an emitter architecture. In some implementations, emitter 100 may correspond to one or more vertical-emitting devices described herein.

As shown in FIG. 1A, emitter 100 may include an implant protection layer 102 that is circular in shape in this example. In some implementations, implant protection layer 102 may have another shape, such as an elliptical shape, a polygonal shape, or the like. Implant protection layer 102 is defined based on a space between sections of implant material (not shown) included in emitter 100.

As shown by the medium gray and dark gray areas in FIG. 1A, emitter 100 includes an ohmic metal layer 104 (e.g., a P-Ohmic metal layer or an N-Ohmic metal layer) that is constructed in a partial ring shape (e.g., with an inner radius and an outer radius). The medium gray area shows an area of ohmic metal layer 104 covered by a protective layer (e.g. a dielectric layer or a passivation layer) of emitter 100 and the dark gray area shows an area of ohmic metal layer 104 exposed by via 106, described below. As shown, ohmic metal layer 104 overlaps with implant protection layer 102. Such a configuration may be used, for example, in the case of a P-up/top-emitting emitter 100. In the case of a bottom-emitting emitter 100, the configuration may be adjusted as needed.

Emitter 100 may include a protective layer (not shown in FIG. 1A) in which via 106 is formed (e.g., etched). The dark gray area shows an area of ohmic metal layer 104 that is exposed by via 106 (e.g., the shape of the dark gray area may be a result of the shape of via 106) while the medium grey area shows an area of ohmic metal layer 104 that is covered by some protective layer. The protective layer may cover all of the emitter other than the vias. As shown, via 106 is formed in a partial ring shape (e.g., similar to ohmic metal layer 104) and is formed over ohmic metal layer 104 such that metallization on the protection layer contacts ohmic metal layer 104. In some implementations, via 106 and/or ohmic metal layer 104 may be formed in another shape, such as a full ring shape or a split ring shape.

As further shown, emitter 100 includes an optical aperture 108 in a portion of emitter 100 within the inner radius of the partial ring shape of ohmic metal layer 104. Emitter 100 emits a laser beam via optical aperture 108. As further shown, emitter 100 also includes a current confinement aperture 110 (e.g., an oxide aperture formed by an oxidation layer of emitter 100 (not shown)). Current confinement aperture 110 is formed below optical aperture 108.

As further shown in FIG. 1A, emitter 100 includes a set of trenches 112 (e.g., oxidation trenches) that are spaced (e.g., equally, unequally) around a circumference of implant protection layer 102. How closely trenches 112 can be positioned relative to the optical aperture 108 is dependent on the application, and is typically limited by implant protection layer 102, ohmic metal layer 104, via 106, and manufacturing tolerances.

The number and arrangement of layers shown in FIG. 1A are provided as an example. In practice, emitter 100 may include additional layers, fewer layers, different layers, or differently arranged layers than those shown in FIG. 1A. For example, while emitter 100 includes a set of six trenches 112, in practice, other configurations are possible, such as a compact emitter that includes five trenches 112, seven trenches 112, or another quantity of trenches. In some implementations, trench 112 may encircle emitter 100 to form a mesa structure dₜ. As another example, while emitter 100 is a circular emitter design, in practice, other designs may be used, such as a rectangular emitter, a hexagonal emitter, an elliptical emitter, or the like. Additionally, or alternatively, a set of layers (e.g., one or more layers) of emitter 100 may perform one or more functions described as being performed by another set of layers of emitter 100, respectively.

Notably, while the design of emitter 100 is described as including a VCSEL, other implementations are possible. For example, the design of emitter 100 may apply in the context of another type of optical device, such as a light emitting diode (LED), or another type of vertical emitting (e.g., top emitting or bottom emitting) optical device. Additionally, the design of emitter 100 may apply to emitters of any wavelength, power level, and/or emission profile. In other words, emitter 100 is not particular to an emitter with a given performance characteristic.

As shown in FIG. 1B, the example cross-sectional view may represent a cross-section of emitter 100 that passes through, or between, a pair of trenches 112 (e.g., as shown by the line labeled “X-X” in FIG. 1A). As shown, emitter 100 may include a backside cathode layer 128, a substrate layer 126, a bottom mirror 124, an active region 122, an oxidation layer 120, a top mirror 118, an implant isolation material 116, a protective layer 114 (e.g. a dielectric passivation/mirror layer), and an ohmic metal layer 104. As shown, emitter 100 may have, for example, a total height that is approximately 10 μm.

Backside cathode layer 128 may include a layer that makes electrical contact with substrate layer 126. For example, backside cathode layer 128 may include an annealed metallization layer, such as an AuGeNi layer, a PdGeAu layer, or the like. Alternatively, a cathode may be on a front side of emitter 100. For example, the cathode may extend through an etched mesa or a trench to substrate layer 126 or to a contact buffer inserted in, or near, bottom mirror 124.

Substrate layer 126 may include a base substrate layer upon which epitaxial layers are grown. For example, substrate layer 126 may include a semiconductor layer, such as a GaAs layer, an InP layer, and/or another type of semiconductor layer.

Bottom mirror 124 may include a bottom reflector layer of emitter 100. For example, bottom mirror 124 may include a DBR (e.g., an n-DBR).

Active region 122 may include a layer that confines electrons and defines an emission wavelength of emitter 100. For example, active region 122 may be a quantum well (e.g., a single quantum well (SQW) or a multi-quantum well (MQW)). In some examples, emitter 100 may include multiple stacked active regions 122 (e.g., two, three, four, five, six, or more active regions 122) with tunnel junctions (TJs) (not shown) between each of the active regions 122.

Oxidation layer 120 may include an oxide layer that provides optical and electrical confinement of emitter 100. In some implementations, oxidation layer 120 may be formed as a result of wet oxidation of an epitaxial layer. For example, oxidation layer 120 may be an Al₂O₃ layer formed as a result of oxidation of an AlAs or AlGaAs layer. Trenches 112 may include openings that allow oxygen (e.g., dry oxygen, wet oxygen) to access the epitaxial layer from which oxidation layer 120 is formed.

Current confinement aperture 110 may include an optically active aperture defined by oxidation layer 120. A size of current confinement aperture 110 may range, for example, from approximately 4 μm to approximately 30 μm, or more or less. In some implementations, a size of current confinement aperture 110 may depend on a distance between trenches 112 that surround emitter 100. For example, trenches 112 may be etched to expose the epitaxial layer from which oxidation layer 120 is formed. Here, before protective layer 114 is formed (e.g., deposited), oxidation of the epitaxial layer may occur for a particular distance (e.g., identified as dₒ in FIG. 1B) toward a center of emitter 100, thereby forming oxidation layer 120 and current confinement aperture 110. In some implementations, current confinement aperture 110 may include an oxide aperture. Additionally, or alternatively, current confinement aperture 110 may include an aperture associated with another type of current confinement technique, such as an etched mesa, a region without ion implantation, lithographically defined intra-cavity mesa and regrowth, or the like.

Top mirror 118 may include a top reflector layer of emitter 100. For example, top mirror 118 may include a DBR (e.g., a p-DBR).

Implant isolation material 116 may include a material that provides electrical isolation. For example, implant isolation material 116 may include an ion implanted material, such as a hydrogen/proton implanted material or a similar implanted element to reduce conductivity. In some implementations, implant isolation material 116 may define implant protection layer 102.

Protective layer 114 may include a layer that acts as a protective passivation layer and which may act as an additional DBR. For example, protective layer 114 may include one or more sub-layers (e.g., a dielectric passivation layer and/or a mirror layer, a SiO₂ layer, a Si₃N₄ layer, an Al₂O₃ layer, or other layers) deposited (e.g., by chemical vapor deposition, atomic layer deposition, or other techniques) on one or more other layers of emitter 100.

As shown, protective layer 114 may include one or more vias 106 that provide electrical access to ohmic metal layer 104. For example, via 106 may be formed as an etched portion of protective layer 114 or a lifted-off section of protective layer 114. Optical aperture 108 may include a portion of protective layer 114 over current confinement aperture 110 through which light may be emitted.

Ohmic metal layer 104 may include a layer that makes electrical contact through which electrical current may flow. For example, ohmic metal layer 104 may include a Ti and Au layer, a Ti and Pt layer and/or an Au layer, or the like, through which electrical current may flow (e.g., through a bondpad (not shown) that contacts ohmic metal layer 104 through via 106). Ohmic metal layer 104 may be P-ohmic, N-ohmic, or other forms known in the art. Selection of a particular type of ohmic metal layer 104 may depend on the architecture of the emitters and is well within the knowledge of a person skilled in the art. Ohmic metal layer 104 may provide ohmic contact between a metal and a semiconductor and/or may provide a non-rectifying electrical junction and/or may provide a low-resistance contact. In some implementations, emitter 100 may be manufactured using a series of steps. For example, bottom mirror 124, active region 122, oxidation layer 120, and top mirror 118 may be epitaxially grown on substrate layer 126, after which ohmic metal layer 104 may be deposited on top mirror 118. Next, trenches 112 may be etched to expose oxidation layer 120 for oxidation. Implant isolation material 116 may be created via ion implantation, after which protective layer 114 may be deposited. Via 106 may be etched in protective layer 114 (e.g., to expose ohmic metal layer 104 for contact). Plating, seeding, and etching may be performed, after which substrate layer 126 may be thinned and/or lapped to a target thickness. Finally, backside cathode layer 128 may be deposited on a bottom side of substrate layer 126.

The number, arrangement, thicknesses, order, symmetry, or the like, of layers shown in FIG. 1B are provided as an example. In practice, emitter 100 may include additional layers, fewer layers, different layers, differently constructed layers, or differently arranged layers than those shown in FIG. 1B. Additionally, or alternatively, a set of layers (e.g., one or more layers) of emitter 100 may perform one or more functions described as being performed by another set of layers of emitter 100 and any layer may comprise more than one layer.

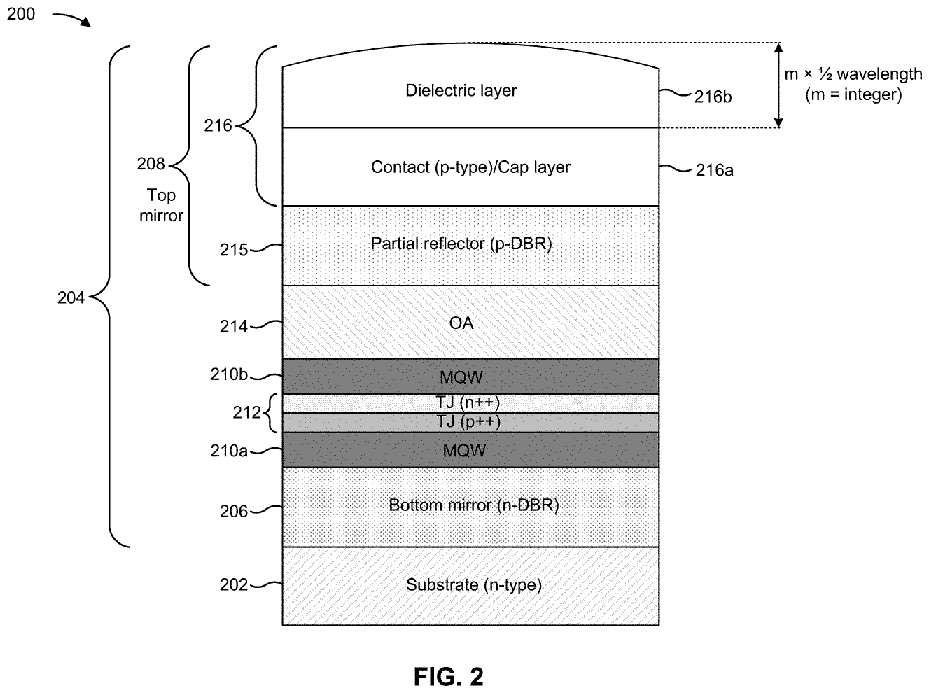

FIG. 2 is a cross-sectional view of an example embodiment of an emitter 200. Emitter 200 may correspond to one or more vertical-emitting devices described herein, such as emitter 100 (e.g., optical aperture 108 of emitter 100). For example, emitter 200 may be a VCSEL. As shown, emitter 200 may include a set of emitter layers constructed in an emitter architecture, as described in connection with FIGS. 1A-1B. In some implementations, emitter 200 is configured to be top-emitting.

Emitter 200 may include a substrate 202 (e.g., an n-type semiconductor substrate) and a set of layers 204 (e.g., epitaxial layers) on the substrate 202. The set of layers 204 may include a first mirror 206 (e.g., a bottom mirror, an n-DBR, or the like), a second mirror 208 (e.g., a top mirror, a p-DBR, or the like), and at least one active region (shown as an MQW) between the first mirror 206 and the second mirror 208. In some implementations, the at least one active region may include one, two, three, four, five, six, or more active regions. For example, as shown, the at least one active region includes a first active region 210a and a second active region 210b, and the set of layers 204 may include a tunnel junction region 212 between the first active region 210a and the second active region 210b.

In some implementations, the set of layers 204 may include an oxidation layer 214 (e.g., corresponding to oxidation layer 120, described herein) that includes an oxidation aperture (OA). For example, the oxidation layer 214 may be between the at least one active region (e.g., the second active region 210b) and the second mirror 208. In some implementations, the set of layers 204 may include one or more additional oxidation layers (not shown). The one or more additional oxidation layers may be located at a p-side and/or an n-side of one or more of the active regions 210a, 210b. For example, an additional oxidation layer may be between the first active region 210a and the tunnel junction region 212, an additional oxidation layer may be between the tunnel junction region 212 and the second active region 210b, an additional oxidation layer may be between the first active region 210a and the first mirror 206, or the like. In some implementations, emitter 200 may be free of an oxidation layer (e.g., emitter 200 may not utilize oxide confinement).

The second mirror 208 may include a partial reflector 215 and an additional layer 216 on the partial reflector 215. The partial reflector 215 may include one or more layers. For example, the partial reflector 215 may include one or more p-type semiconductor layers, one or more undoped semiconductor layers, or the like. In one example, the partial reflector 215 may include a DBR (e.g., a p-DBR), multiple layers of the DBR, or a single layer of the DBR. The additional layer 216 may include one or more layers. For example, the additional layer 216 may include a contact layer (e.g., a semiconductor contact layer, a p-type contact layer, or the like) and/or a cap layer (e.g., a semiconductor cap layer, a p-type cap layer, multiple layers of the DBR, a single layer of the DBR, or the like), and/or a dielectric layer, among other examples. For example, the contact layer and/or the cap layer may be on the partial reflector 215 (e.g., DBR), and the dielectric layer may be on the contact layer and/or the cap layer. In some implementations, the partial reflector 215 (e.g., DBR) may act in concert with the additional layer 216 (e.g., additional DBR) as a reflector. For example, the partial reflector 215 and the additional layer 216 may together define the second mirror 208 (e.g., a top mirror) of emitter 200. As an example, the partial reflector 215 may include one or more first layers of a DBR, and the additional layer 216 may include one or more second layers of the DBR.

The second mirror 208 may be configured for variable light reflectivity, as described herein. In some implementations, a first reflectivity of the second mirror 208 at a lateral center of the second mirror 208 (e.g., an axial center in a direction of light emission of emitter 200) is different from a second reflectivity of the second mirror 208 at a lateral edge of the second mirror 208 (e.g., relative to a direction of light emission of emitter 200). For example, the first reflectivity may be greater than the second reflectivity to improve low-order mode lasing.

In some implementations, a first thickness (e.g., in a direction of light emission of emitter 200) at the lateral center of the second mirror 208 may be different than a second thickness at the lateral edge of the second mirror 208 (e.g., a difference of 5% or more, 10% or more, 15% or more, 20% or more, 25% or more, 30% or more, or 35% or more), so that the first reflectivity is different than the second reflectivity. That is, a thickness of the second mirror 208 may vary from the lateral center to the lateral edge of the second mirror 208. In some examples, the thickness may vary continuously from the lateral center to the lateral edge of the second mirror 208. In some other examples, the thickness may vary over one or more first segments of the second mirror 208, and the thickness may not vary over one or more second segments of the second mirror 208.

In some implementations, as shown in FIG. 2, a surface of the second mirror 208 (e.g., of the additional layer 216) is curved from the lateral center to the lateral edge of the second mirror 208 (e.g., a maximum point or a minimum point of the curve is aligned with a center of the emitter 200). That is, the surface of the second mirror 208 (e.g., of the additional layer 216) has a curvature (e.g., is non-flat). As shown in FIG. 2, the curvature may be a convex (i.e., dome-shaped) curvature (e.g., the first thickness at the lateral center of the second mirror 208 is greater than the second thickness at the lateral edge of the second mirror 208).

In some implementations, the curvature of the surface of the second mirror 208 (e.g., of the additional layer 216) may correspond to a section of a cylinder or a section of a parabolic cylinder. For example, the surface may be curved along a first dimension orthogonal to a direction of light emission of emitter 200, and the surface may not be curved along a second dimension orthogonal to the direction of light emission and orthogonal to the first dimension (e.g., the surface may have a shape corresponding to a lengthwise cross-section of a cylinder). In some implementations, the curvature of the surface of the second mirror 208 (e.g., of the additional layer 216) may correspond to a section of a sphere or a section of a paraboloid. For example, the surface may be curved along the first dimension and curved along the second dimension. In some implementations, a first portion of the surface of the second mirror 208 (e.g., of the additional layer 216), that includes the lateral center, may have no curvature (e.g., flat) or may have a lesser degree of curvature, and a second portion of the surface, that includes the lateral edge, may have curvature or may have a greater degree of curvature. In other words, a first segment of the second mirror 208 (e.g., of the additional layer 216), that includes the lateral center, may have a uniform thickness or may have less variation in thickness, and a second segment of the second mirror 208 (e.g., of the additional layer 216), that includes the lateral edge, may have a thickness that varies or may have greater variation in thickness.

Varying the thickness of the second mirror 208 provides relatively higher reflectivity at the center of emitter 200, and relatively lower reflectivity at the edges of emitter 200. Thus, the edges may experience greater transmission loss. For example, because a high-order modes profile may be closer to the edges, these modes will experience greater loss. Therefore, the variable light reflectivity of emitter 200 can enhance mode filtering and selection.

The additional layer 216 may have a lower layer 216a (e.g., a layer between a top-most layer of emitter 200 and the partial reflector 215) and an upper layer 216b (e.g., a top-most layer of emitter 200). As shown in FIG. 2, the upper layer 216b of the additional layer 216 may vary in thickness, have a curved surface, or the like, as described herein. For example, the upper layer 216b may have a convex surface. The upper layer 216b of the additional layer 216 may include the dielectric layer. The dielectric layer may include a single layer (e.g., with a composition of SiNₓ, SiOₓ, SiNₓO_{y}, or the like). Alternatively, the dielectric layer may include multiple layers (e.g., of different compositions of SiNₓ, SiOₓ, SiNₓO_{y}, or the like) to produce an additional dielectric mirror (e.g., an additional dielectric DBR mirror). The dielectric layer, or each layer of the multiple layers, may have a refractive index in a range from about 1.3 to about 2.3. In some implementations, the refractive index may be greater than 2.3 or less than 1.3 depending on the composition of the dielectric layer and/or the deposition process used for the dielectric layer. The refractive index of the dielectric layer may be a value that is between the refractive index of air and the refractive index of III-V semiconductors, such as GaAs, AlGaAs, InP, InGaAs, or alloys thereof.

As shown in FIG. 2, the upper layer 216b (e.g., the dielectric layer) of the additional layer 216 may have an optical thickness, at the lateral center of the upper layer 216b, that is an integer multiple of the half-wavelength (e.g., ½, 1, 3/2, or the like) of emitter 200. In this way, reflectivity at the lateral center is maximized to thereby provide maximum feedback for lasing.

In some implementations, the second mirror 208 may be configured for variable light reflectivity by varying a refractive index of the second mirror 208 (e.g., of the additional layer 216). For example, a first refractive index at the lateral center of the second mirror 208 may be different than (e.g., greater than) a second refractive index at the lateral edge of the second mirror 208. That is, a refractive index of the second mirror 208 may vary from the lateral center to the lateral edge of the second mirror 208, in a similar manner in which the thickness may vary, as described above.

The number, arrangement, thicknesses, order, symmetry, or the like, of layers shown in FIG. 2 is provided as an example. In practice, emitter 200 may include additional layers, fewer layers, different layers, differently constructed layers, or differently arranged layers than those shown in FIG. 2. For example, emitter 200 may include one or more cladding layers, one or more spacer layers, and/or one or more additional mirror layers (e.g., DBR layers), among other examples. Additionally, or alternatively, a set of layers (e.g., one or more layers) of emitter 200 may perform one or more functions described as being performed by another set of layers of emitter 200 and any layer may comprise more than one layer.

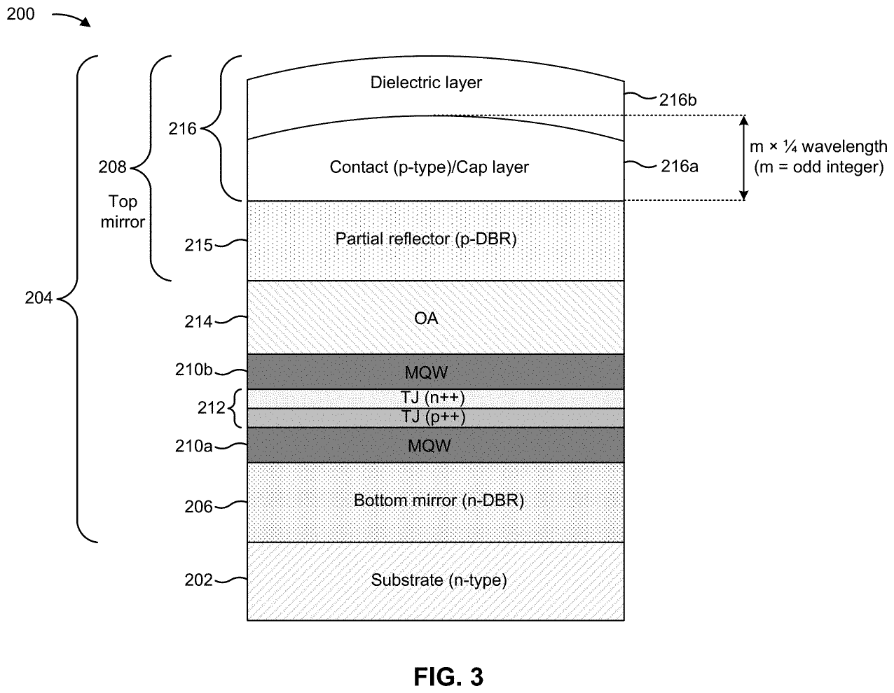

FIG. 3 is a cross-sectional view of another example embodiment of emitter 200. As shown in FIG. 3, a lower layer 216a of the additional layer 216 may vary in thickness, have a curved surface, or the like, as described herein. For example, the lower layer 216a may have a convex surface, as shown. The lower layer 216a of the additional layer 216 may include the contact layer (e.g., a semiconductor contact layer, a p-type contact layer, or the like) and/or the cap layer (e.g., a semiconductor cap layer, a p-type cap layer, or the like). The contact layer and/or the cap layer may include a p-type semiconductor or an n-type semiconductor. For an n-type semiconductor, the second mirror 208 may include n-DBR by including an additional tunnel junction in the set of layers 204. In some implementations, the second mirror 208 may include undoped semiconductor layers on layer 216a and/or layer 215 (e.g., if an anode extends through an etched mesa or a trench to doped layers).

As shown in FIG. 3, the lower layer 216a (e.g., the contact layer and/or the cap layer) of the additional layer 216 may have an optical thickness, at the lateral center of the lower layer 216a, that is an odd integer multiple of the quarter-wavelength (e.g., ¼, ¾, 5/4, or the like) of emitter 200, which maximizes reflectivity and maximizes feedback to enhance lasing. The upper layer 216b (e.g., the dielectric layer) of the additional layer 216 may be deposited on the lower layer 216a that is configured for variable light reflectivity. Thus, the upper layer 216b may also have a curved surface (e.g., a convex surface) that corresponds to the curvature of the surface of the lower layer 216a. In some implementations, the upper layer 216b may have a curvature that is different from a curvature of the lower layer 216a (e.g., after depositing the upper layer 216b, a differently curved surface may be formed on the upper layer 216b).

As indicated above, FIG. 3 is provided as an example. Other examples may differ from what is described with regard to FIG. 3.

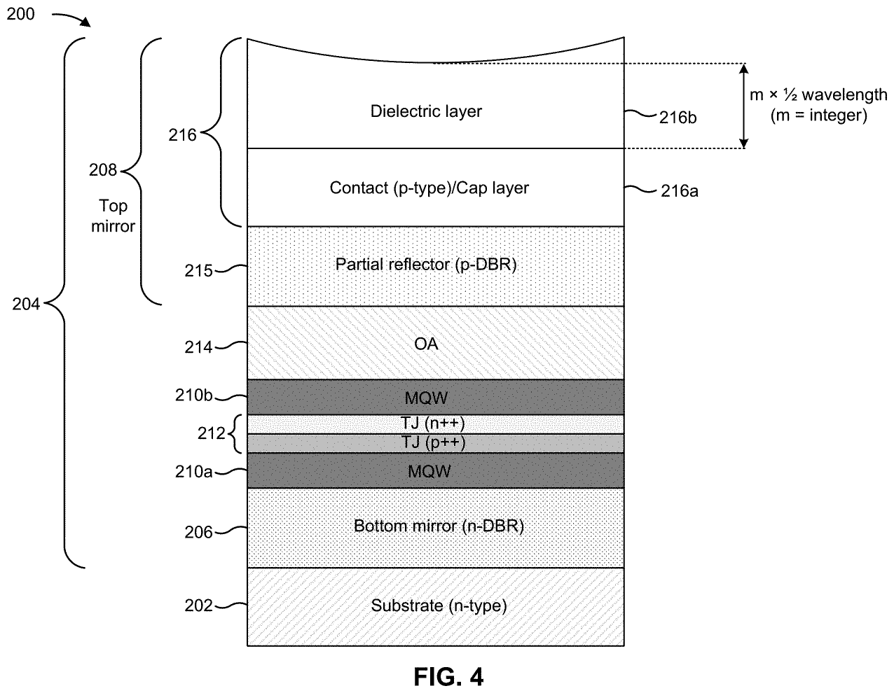

FIG. 4 is a cross-sectional view of another example embodiment of emitter 200. As shown in FIG. 4, the first thickness at the lateral center of the second mirror 208 may be less than the second thickness at the lateral edge of the second mirror 208, so that the first reflectivity at the lateral center is different than the second reflectivity at the lateral edge. For example, the curvature of the surface of the second mirror 208 (e.g., of the additional layer 216) may be a concave curvature. As shown in FIG. 4, the upper layer 216b (e.g., the dielectric layer) of the additional layer 216 may have a concave surface.

As indicated above, FIG. 4 is provided as an example. Other examples may differ from what is described with regard to FIG. 4.

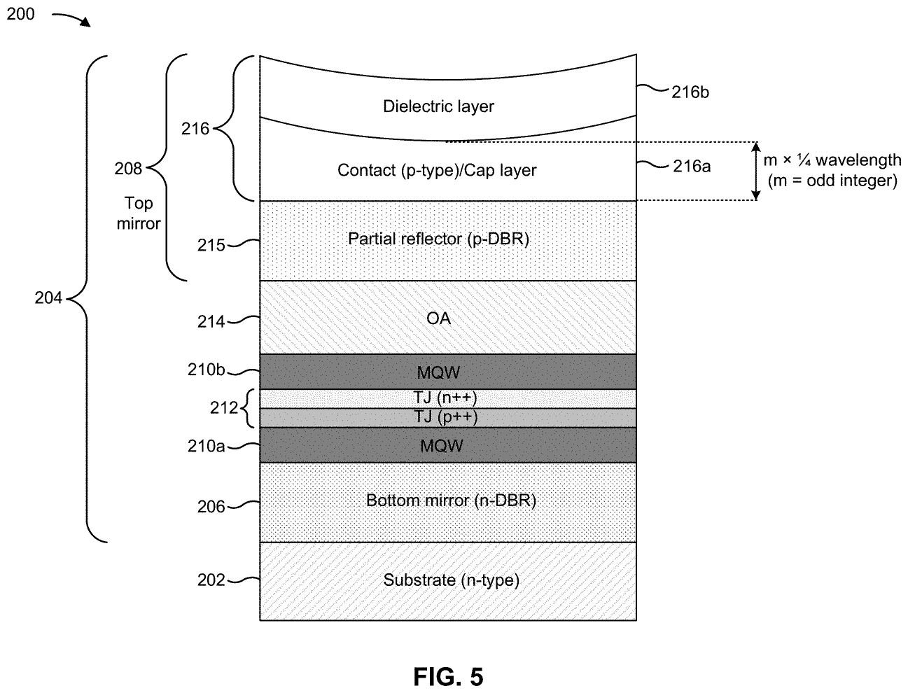

FIG. 5 is a cross-sectional view of another example embodiment of emitter 200. As shown in FIG. 5, the lower layer 216a (e.g., the contact layer and/or the cap layer) of the additional layer 216 may have a concave surface, as described above. The upper layer 216b (e.g., the dielectric layer) of the additional layer 216 may be deposited on the lower layer 216a. Thus, the upper layer 216b may also have a curved surface (e.g., a concave surface) that corresponds to the curvature of the surface of the lower layer 216a. In some implementations, the upper layer 216b may have a curvature that is different from a curvature of the lower layer 216a.

As indicated above, FIG. 5 is provided as an example. Other examples may differ from what is described with regard to FIG. 5.

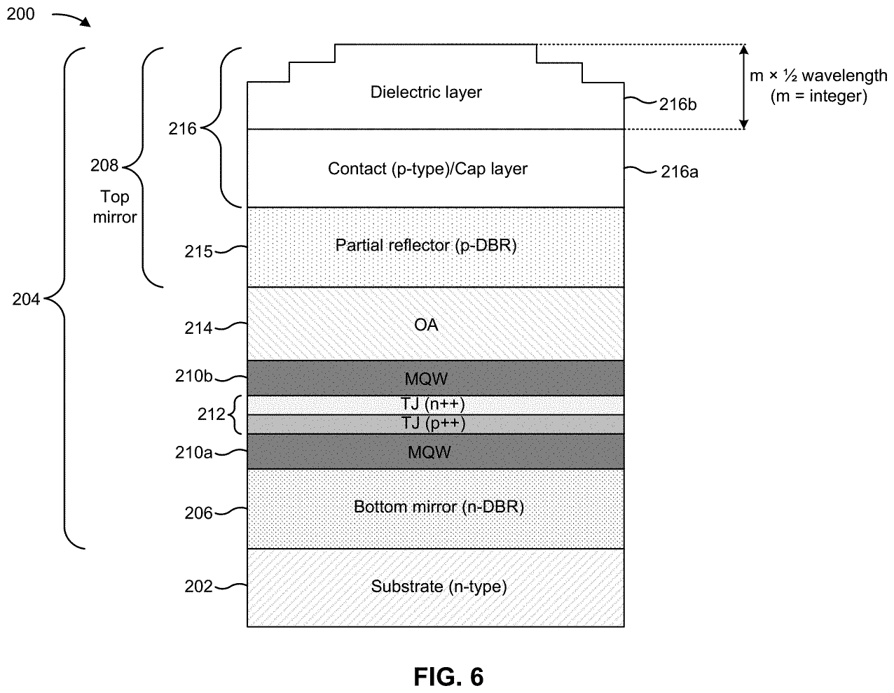

FIG. 6 is a cross-sectional view of another example embodiment of emitter 200. As shown in FIG. 6, the surface of the second mirror 208 may be stepped from the lateral center to the lateral edge of the second mirror 208 (so that the first thickness at the lateral center of the second mirror 208 is different than the second thickness at the lateral edge of the second mirror 208). That is, the surface of the additional layer 216 has one or more steps. A step may include a flat surface that is relatively higher than an adjacent flat surface (e.g., an adjacent step) and/or relatively lower than an adjacent flat surface (e.g., an adjacent step). In some implementations, the one or more steps may have uniform widths (e.g., in a direction orthogonal to light emission of emitter 200). In some implementations, a width of a first step may be different than a width of a second step. For example, as shown, a width of a step that includes the lateral center of the second mirror 208 may be different than (e.g., greater than) a width of a step that includes the lateral edge of the second mirror 208.

In some implementations, the steps may be concentric. For example, a first step, at the lateral center of the second mirror 208 (e.g., of the additional layer 216), may be surrounded (or partially surrounded) by a second step, and so forth (e.g., to provide multiple terraces on the surface of the second mirror 208). In some implementations, the steps of the surface of the second mirror 208 (e.g., of the additional layer 216) may be side-by-side. For example, the steps may include multiple strips that extend parallel between opposite lateral edges of the second mirror 208. As shown in FIG. 6, the first thickness at the lateral center of the second mirror 208 (e.g., of the additional layer 216) may be greater than the second thickness at the lateral edge of the second mirror 208 (e.g., of the additional layer 216). In other words, the steps may ascend from the lateral edge of the second mirror 208 to the lateral center of the second mirror 208.

As shown in FIG. 6, the upper layer 216b (e.g., the dielectric layer) of the additional layer 216 may have a stepped surface. In some implementations, the lower layer 216a (e.g., the contact layer and/or the cap layer) of the additional layer 216 may have a stepped surface, and the upper layer 216b may be deposited on the lower layer 216a, such that the upper layer 216b also has a stepped surface. In some implementations, a stepped surface of the upper layer 216b may have a configuration that is different from a configuration for a stepped surface of the lower layer 216a (e.g., the upper layer 216b and the lower layer 216a may have different quantities of steps, different step widths, different step orientations, or the like). In some implementations, one of the upper layer 216b and the lower layer 216a may have a curved surface, as described above, and the other of the upper layer 216b and the lower layer 216a may have a stepped surface.

As indicated above, FIG. 6 is provided as an example. Other examples may differ from what is described with regard to FIG. 6.

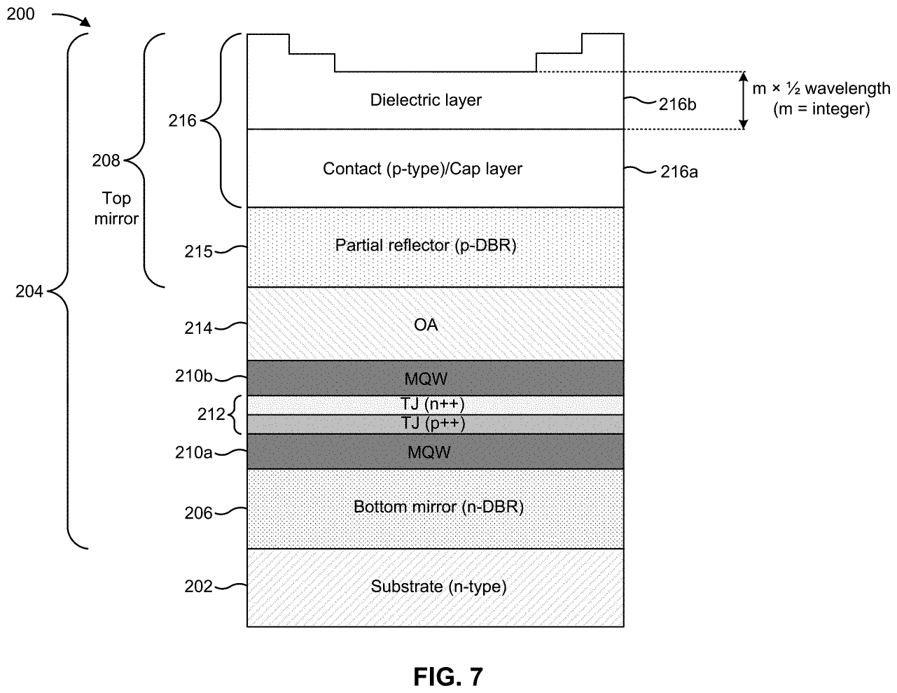

FIG. 7 is a cross-sectional view of another example embodiment of emitter 200. FIG. 7 shows the second mirror 208 with a stepped surface, as described above. As shown in FIG. 7, the first thickness at the lateral center of the second mirror 208 (e.g., of the additional layer 216) may be less than the second thickness at the lateral edge of the second mirror 208 (e.g., of the additional layer 216). In other words, the steps may descend from the lateral edge of the second mirror 208 to the lateral center of the second mirror 208.

As indicated above, FIG. 7 is provided as an example. Other examples may differ from what is described with regard to FIG. 7.

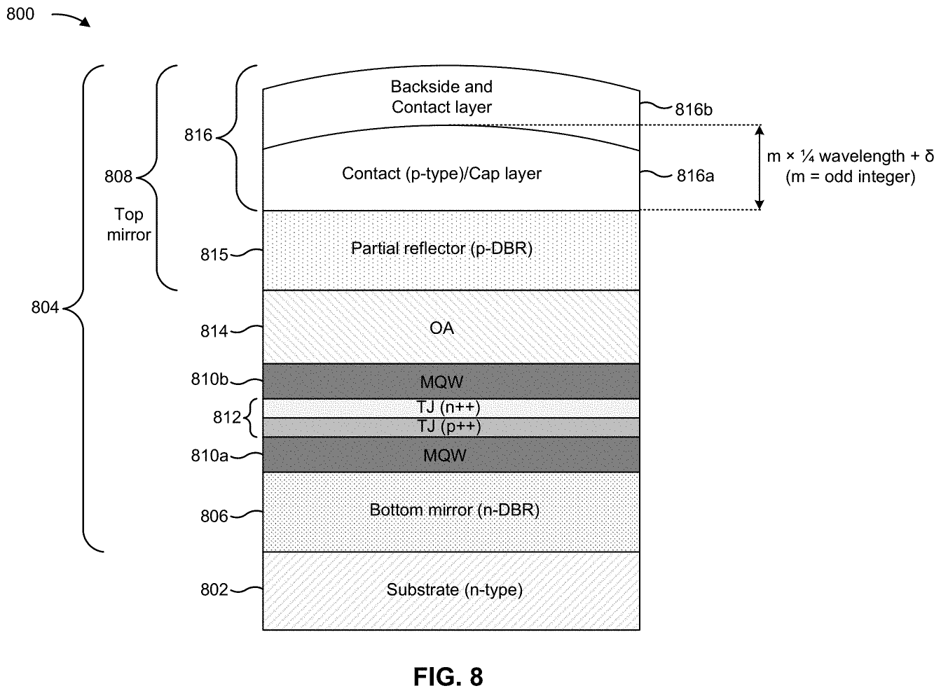

FIG. 8 is a cross-sectional view of an example embodiment of an emitter 800. Emitter 800 may correspond to one or more vertical-emitting devices described herein, such as emitter 100 (e.g., optical aperture 108 of emitter 100). For example, emitter 800 may be a VCSEL. As shown, emitter 800 may include a set of emitter layers constructed in an emitter architecture, as described in connection with FIGS. 1A-1B. In some implementations, emitter 800 is configured to be bottom-emitting.

Emitter 800 may include a substrate 802 and a set of layers 804 (e.g., epitaxial layers), on the substrate 802, that include a first mirror 806, a second mirror 808, at least one active region (e.g., a first active region 810a and a second active region 810b with a tunnel junction region 812 therebetween) between the first mirror 806 and the second mirror 808, and/or an oxidation layer 814, in a similar manner as described in connection with FIG. 2. In addition, the second mirror 808 may include a partial reflector 815 and an additional layer 816 on the partial reflector 815. The partial reflector 815 may include one or more layers, as described above. For example, the partial reflector 815 may include one or more p-type semiconductor layers, one or more undoped semiconductor layers, a DBR (e.g., a p-DBR), multiple layers of the DBR, or a single layer of the DBR. The additional layer 816 may include one or more layers. For example, the additional layer 816 may include a contact layer (e.g., a semiconductor contact layer, a p-type contact layer, or the like) and/or a cap layer (e.g., a semiconductor cap layer, a p-type cap layer, multiple layers of the DBR, a single layer of the DBR, or the like), a dielectric layer, and/or a backside and contact layer (e.g., a backside and contact metal layer), among other examples. For example, the contact layer and/or the cap layer may be on the partial reflector 815 (e.g., DBR), and the backside and contact layer may be on the contact layer and/or the cap layer. In some implementations, the partial reflector 815 (e.g., DBR) and the additional layer 816 may together define a reflector of emitter 800, in a similar manner as described in connection with FIG. 2.

In some implementations, the second mirror 808 (e.g., for a bottom-emitting configuration) may be configured for variable light reflectivity, as described above. For example, the second mirror 808 (e.g., the additional layer 816) may have a thickness that varies from a lateral center of the second mirror 808 to a lateral edge of the second mirror 808, as described above. In other words, the second mirror 808 (e.g., the additional layer 816) may have a curved surface or a stepped surface, as described above.

The additional layer 816 may have a lower layer 816a and an upper layer 816b, as described above. As shown in FIG. 8, the lower layer 816a of the additional layer 816 may have a curved surface (e.g., a convex surface or a concave surface), as described above. As shown in FIG. 8, the lower layer 816a (e.g., the contact layer and/or the cap layer) of the additional layer 816 may have an optical thickness, at the lateral center of the lower layer 816a, that is an odd integer multiple of the quarter-wavelength (e.g., ¼, ¾, 5/4, or the like) of emitter 800 adjusted by an amount δ. The amount δ may have a value that compensates for phase shift caused by the upper layer 816b (e.g., the backside and contact layer) of the additional layer 816. The upper layer 816b may be deposited on the lower layer 816a. Thus, the upper layer 816b may also have a curved surface that corresponds to the curvature of the surface of the lower layer 816a. In some implementations, the upper layer 816b may have a curvature that is different from a curvature of the lower layer 816a.

In some implementations, the upper layer 816b of the additional layer 816 may have a curved surface, and the surface of the lower layer 816a of the additional layer 816 may not be curved. In some implementations, the upper layer 816b of the additional layer 816 and/or the lower layer 816a of the additional layer 816 may have a stepped surface, as described above. In an example, one of the upper layer 816b and the lower layer 816a may have a curved surface, and the other of the upper layer 816b and the lower layer 816a may have a stepped surface. In some implementations, the second mirror 808 may be configured for variable light reflectivity by varying a refractive index of the second mirror 808, as described above.

The number, arrangement, thicknesses, order, symmetry, or the like, of layers shown in FIG. 8 is provided as an example. In practice, emitter 800 may include additional layers, fewer layers, different layers, differently constructed layers, or differently arranged layers than those shown in FIG. 8. For example, emitter 800 may include one or more cladding layers, one or more spacer layers, and/or one or more additional mirror layers (e.g., DBR layers), among other examples. Additionally, or alternatively, a set of layers (e.g., one or more layers) of emitter 800 may perform one or more functions described as being performed by another set of layers of emitter 800 and any layer may comprise more than one layer.

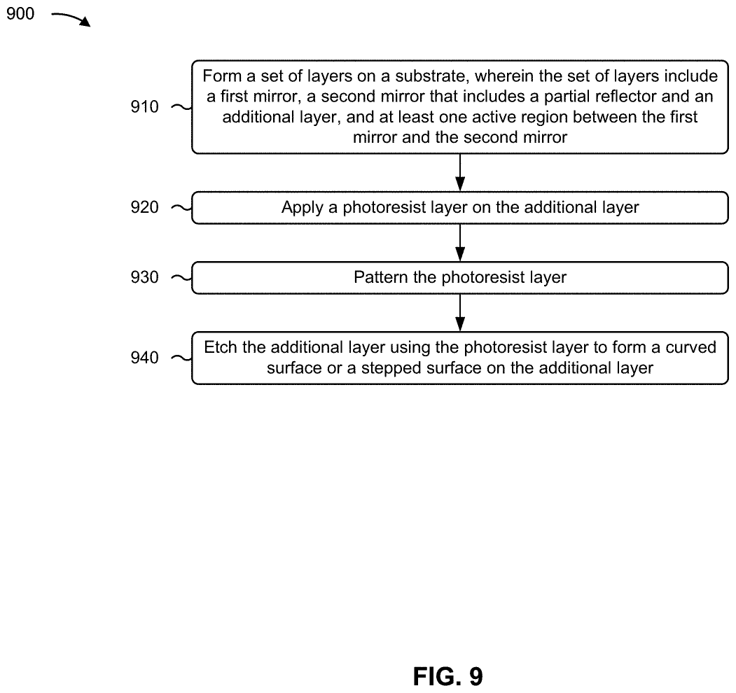

FIG. 9 is a flowchart of an example process 900 relating to forming an emitter with variable light reflectivity, as described above. For example, FIG. 9 shows an example process 900 for producing emitter 200 (e.g., as described in connection with FIGS. 2-7) and/or emitter 800 described above.

As shown in FIG. 9, process 900 may include forming a set of layers on a substrate (block 910). For example, process 900 may include forming, on a substrate (e.g., the substrate 202 or 802), a set of layers (e.g., the set of layers 204 or 804) that include a first mirror (e.g., the first mirror 206 or 806), a second mirror (e.g., the second mirror 208 or 808), and at least one active region (e.g., the active regions 210a and 210b or 810a and 810b) between the first mirror and the second mirror, in a manner that is the same or similar to that described elsewhere herein. The second mirror may include a partial reflector (e.g., the partial reflector 215 or 815) and an additional layer (e.g., the additional layer 216 or 816) on the partial reflector, in a manner that is the same as or similar to that described elsewhere herein. The partial reflector may include one or more doped semiconductor layers (e.g., p-type semiconductor layers), one or more undoped semiconductor layers, a DBR, multiple layers of the DBR, a single layer of the DBR, or the like. The additional layer may include a semiconductor contact layer and/or a semiconductor cap layer, a dielectric layer, multiple layers of the DBR, a single layer of the DBR, or the like. Forming the set of layers on the substrate may produce an emitter (e.g., emitter 200 or 800). In some implementations, the emitter may be top-emitting or bottom-emitting.

As further shown in FIG. 9, process 900 may include applying a photoresist layer on the additional layer (block 920). The photoresist layer may include one or more photoactive compounds. In some implementations, in connection with producing a stepped surface on the additional layer, the photoresist layer is a first photoresist layer for application on the additional layer.

As further shown in FIG. 9, process 900 may include patterning the photoresist layer (block 930). The photoresist layer may be patterned using a photomask. For example, the photomask may be applied to the photoresist layer and exposed to light to thereby pattern the photoresist layer.

In some implementations, the photoresist layer may be patterned using a grayscale photomask. The grayscale photomask may be configured to pattern the photoresist layer in a manner to define a curved surface on the additional layer (e.g., such that a maximum point or a minimum point of the curve is aligned with a center of the emitter 200). In some implementations, in connection with producing a stepped surface on the additional layer, the photoresist layer (e.g., the first photoresist layer) is patterned using a photomask (e.g., a first photomask) configured to pattern the photoresist layer in a manner to define a step (e.g., a first step) of the stepped surface on the additional layer.

As further shown in FIG. 9, process 900 may include etching (e.g., dry etching) the additional layer using the photoresist layer to form a curved surface or a stepped surface on the additional layer (block 940). For example, the curved surface may be formed by etching the additional layer using the photoresist layer patterned using the grayscale photomask. As another example, the stepped surface may be formed by etching the additional layer using the first photoresist layer patterned using the first photomask.

Process 900 may include additional implementations, such as any single implementation or any combination of implementations described below and/or in connection with one or more other processes described elsewhere herein.

The first photoresist layer patterned using the first photomask may be used to form a first step of the stepped surface on the additional layer. In some implementations, process 900 may further include forming one or more additional steps of the stepped surface. For example, process 900 may further include depositing an additional portion of the additional layer on the stepped surface. For example, a first portion of the additional layer may be deposited in block 910, and a second portion of the additional layer may be deposited on the first portion of the additional layer after forming a first step of the stepped surface on the first portion of the additional layer.

Process 900 may further include applying a second photoresist layer on the additional layer (e.g., on the second portion of the additional layer), in a similar manner as described above. Process 900 may further include patterning the second photoresist layer. For example, the second photoresist layer may be patterned using a second photomask that is different than the first photomask. The second photomask may be configured to pattern the second photoresist layer in a manner to define a second step (e.g., adjacent to the first step) of the stepped surface on the additional layer.

Process 900 may further include etching the additional layer using the second photoresist layer to form a second step of the stepped surface on the additional layer. Process 900 may include one or more additional iterations of depositing a portion (e.g., a third portion, a fourth portion, etc.) of the additional layer, applying a photoresist layer (e.g., a third photoresist layer, a fourth photoresist layer, etc.), patterning the photoresist layer (e.g., using a third photomask, a fourth photomask, etc.), and etching the additional layer to form additional steps (e.g., a third step, a fourth step, etc.) of the stepped surface.

Although FIG. 9 shows example blocks of process 900, in some implementations, process 900 may include additional blocks, fewer blocks, different blocks, or differently arranged blocks than those depicted in FIG. 9. Additionally, or alternatively, two or more of the blocks of process 900 may be performed in parallel.

In some implementations, an emitter described herein may include a curved surface and a stepped surface, as described above. That is, a first portion of the emitter's surface may be curved, as described above, and a second portion of the emitter's surface may be stepped, as described above. In some implementations, a shape of a curved surface and/or a stepped surface used by an emitter may be irregular, non-symmetrical, employ various geometries, or the like (e.g., in order to target particular lateral modes or to achieve a particular far-field beam profile). In some implementations, an array of emitters may include a plurality of emitters 200 (e.g., as described in connection with FIGS. 2-7) or a plurality of emitters 800. For example, the array of emitters may uniformly have curved surfaces and/or stepped surfaces, as described herein.

According to some implementations, a method may include generating (or forming) an array of light spots for 3D sensing using the emitter 200 (or an array thereof) or the emitter 800 (or an array thereof). According to some implementations, a method may include generating (or forming) a light pattern for 3D sensing using the emitter 200 (or an array thereof) or the emitter 800 (or an array thereof). According to some implementations, a method may include generating an optical signal for LIDAR-based measurement using the emitter 200 (or an array thereof) or the emitter 800 (or an array thereof); and/or detecting an object based on the optical signal.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “higher,” “above,” “upper,” “top,” “bottom,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A vertical cavity surface emitting laser (VCSEL), comprising:
a substrate; and
a set of layers on the substrate, the set of layers comprising:
a first mirror;
a second mirror that includes a partial reflector and an additional layer; and
at least one active region between the first mirror and the second mirror,
wherein a first thickness of the second mirror at a lateral center of the second mirror is different than a second thickness of the second mirror at a lateral edge of the second mirror.

2. The VCSEL of claim 1, wherein the partial reflector comprises one or more layers of a distributed Bragg reflector.

3. The VCSEL of claim 1, wherein the at least one active region comprises a first active region and a second active region, and
wherein the set of layers further comprise a tunnel junction region between the first active region and the second active region.

4. The VCSEL of claim 1, wherein the first thickness is greater than the second thickness.

5. The VCSEL of claim 1, wherein the second thickness is greater than the first thickness.

6. The VCSEL of claim 1, wherein the additional layer comprises one or more of:
a contact layer;
a cap layer; or
a dielectric layer.

7. The VCSEL of claim 1, wherein the additional layer comprises:
a contact layer on the partial reflector; and
a dielectric layer on the contact layer.

8. The VCSEL of claim 7, wherein a surface of the dielectric layer is curved or stepped.

9. The VCSEL of claim 7, wherein a surface of the dielectric layer is curved or stepped, and a surface of the contact layer is curved or stepped.

10. An emitter, comprising:
a substrate; and
a set of layers on the substrate, the set of layers comprising:
a first mirror;
a second mirror that includes a partial reflector and an additional layer; and
at least one active region between the first mirror and the second mirror,
wherein a first reflectivity of the second mirror at a lateral center of the second mirror is different than a second reflectivity of the second mirror at a lateral edge of the second mirror.

11. The emitter of claim 10, wherein the partial reflector comprises one or more layers of a distributed Bragg reflector.

12. The emitter of claim 10, wherein the at least one active region comprises a first active region and a second active region, and
wherein the set of layers further comprise a tunnel junction region between the first active region and the second active region.

13. The emitter of claim 10, wherein a surface of the second mirror is curved from the lateral center of the second mirror to the lateral edge of the second mirror.

14. The emitter of claim 10, wherein a surface of the second mirror is stepped from the lateral center of the second mirror to the lateral edge of the second mirror.

15. The emitter of claim 10, wherein a first thickness of the second mirror at the lateral center of the second mirror is different than a second thickness of the second mirror at the lateral edge of the second mirror.

16. The emitter of claim 10, wherein the additional layer comprises one or more of:
a contact layer;
a cap layer; or
a dielectric layer.

17. A method, comprising:
forming a set of layers on a substrate,
wherein the set of layers include a first mirror, a second mirror that includes a partial reflector and an additional layer, and at least one active region between the first mirror and the second mirror;
applying a photoresist layer on the additional layer;
patterning the photoresist layer; and
etching the additional layer using the photoresist layer to form a curved surface or a stepped surface on the additional layer.

18. The method of claim 17, wherein the photoresist layer is patterned using a grayscale photomask to define the curved surface on the additional layer.

19. The method of claim 17, wherein the photoresist layer is a first photoresist layer patterned using a first photomask to define a first step of the stepped surface on the additional layer, and
wherein the method further comprises:
depositing an additional portion of the additional layer on the stepped surface;
applying a second photoresist layer on the additional layer;
patterning the second photoresist layer; and
etching the additional layer using the second photoresist layer to form a second step of the stepped surface on the additional layer.

20. The method of claim 17, wherein a first thickness of the second mirror at a lateral center of the second mirror is different than a second thickness of the second mirror at a lateral edge of the second mirror based on etching the additional layer.
